(19) United States
(12) Patent Application Publication
(10) Pub. No.: US 2018/0046083 A1
(43) Pub. Date: Feb. 15, 2018

(54) PROCESSING LIQUID SUPPLYING APPARATUS AND METHOD OF CONTROLLING PROCESSING LIQUID SUPPLYING APPARATUS

(71) Applicant: SCREEN Holdings Co., Ltd., Kyoto (JP)

(72) Inventor: Masahito KASHIYAMA, Kyoto-shi, Kyoto (JP)

(21) Appl. No.: 15/556,517

(22) PCT Filed: Feb. 12, 2016
(86) PCT No.: PCT/JP2016/054174

§ 371 Date: Sep. 7, 2017

(30) Foreign Application Priority Data
Mar. 27, 2015 (JP) 2015-066617

(51) Int. Cl. G03F 7/30

(52) U.S. Cl. CPC G03F 7/30; H01L 21/027

(57) ABSTRACT

Provided downstream of an on-off valve are a needle and a diaphragm that cooperates with the needle. The needle is driven by a motor. A controller causes the motor to move the diaphragm cooperating with the needle for increasing a volume of a flow path downstream of the on-off valve. Accordingly, this allows suck back, leading to prevention of drips of the processing liquid. In addition, the controller causes the motor to move the needle for regulating the flow rate of the processing liquid when the on-off valve is opened. This facilitates flow regulation of the processing liquid by the motor which is current1y made by the operator's sense. Moreover, since prevention of the drips of the processing liquid as well as the flow regulation of the processing liquid are performable with the same motor, a needless configuration is omittable to achieve space saving.

### TECHNICAL FIELD

The present invention relates to a processing liquid supplying apparatus and a method of controlling the processing liquid supplying apparatus that supplies a processing liquid to substrates such as semiconductor substrates, glass substrates for liquid crystal display, glass substrates for photomask, and optical disk substrates.

### BACKGROUND ART

As illustrated in FIG. 8, a current1y-used processing liquid supplying apparatus includes a dispensing nozzle 111 that dispenses a developer as a processing liquid, a developer supplying source 113, and a pipe 115 that feeds the developer from the developer supplying source 113 to the dispensing nozzle 111. A pump P and an on-off valve 117 are interposingly arranged on the pipe 115.

The on-off valve 117 allows flow regulation, and operates by taking in and out gas with a gas supplying unit 147. Moreover, an operator rotates a flow regulating handle 118 of the on-off valve 117 to cause a desired flow rate of developer to pass while the on-off valve 117 is on (i.e., in an opened condition).

When a photoresist is supplied as the processing liquid, the current1y-used processing liquid supplying apparatus includes a suck back valve disposed between the dispensing nozzle 111 and the on-off valve 117. See, for example, Patent Literature 1.

Patent Literature 1: Japanese Patent No. 5442232B

### SUMMARY OF INVENTION

### Technical Problem

In the case of supplying not only the photoresist but also the developer, it is desired to prevent drips of the developer onto the substrate. In addition, the flow of the developer is regulated by rotating the flow regulating handle 118 with an operator's sense, leading to difficulty in flow regulation. Accordingly, it is desired to facilitate the flow regulation of the processing liquid. Moreover, if a large flow rate of developer passes through the pipe, a water hammer as an impact caused by closing the flow path by the on-off valve causes the developer to be interrupted, and thus the developer drips. Then, it is desired to prevent the drips certainly.

The present invention has been made regarding the state of the art noted above, and its primary object is to provide a processing liquid supplying apparatus and a method of controlling the processing liquid supplying apparatus that allows prevention of drips of a processing liquid and flow regulation of the processing liquid with a rational configuration. Another secondary object is to provide a processing liquid supplying apparatus and a method of controlling the processing liquid supplying apparatus that allows certain prevention of the drips.

### Solution to Problem

The present invention is constituted as stated below to achieve the above object. One aspect of the present invention provides a processing liquid supplying apparatus, the apparatus including a processing liquid flow path that passes a processing liquid, an on-off valve that opens/closes the processing liquid flow path, a valve element disposed downstream of the on-off valve for adjusting an aperture of the processing liquid flow path, a volume variation unit disposed downstream of the on-off valve for cooperating with the valve element to vary a volume of a downstream processing liquid flow path disposed downstream of the on-off valve, a valve element drive unit that drives the valve element, and a controller that causes the valve element drive unit to move the volume variation unit cooperating with the valve element for increasing the volume of the downstream processing liquid flow path when the on-off valve closes the processing liquid flow path, and causes the valve element drive unit to move the valve element for regulating a flow rate of the processing liquid when the on-off valve opens the processing liquid flow path.

With the processing liquid supplying apparatus according to the aspect of the present invention, disposed downstream of the on-off valve that opens/closes the processing liquid flow path are the valve element that adjust the aperture of the processing liquid flow path, and the volume variation unit that cooperates with the valve element to vary the volume of the downstream processing liquid flow path disposed downstream of the on-off valve. The valve element is driven by the valve element drive unit. The controller causes the valve element to move the volume variation unit cooperating with by the valve element drive unit for increasing the volume of the downstream processing liquid flow path when the on-off valve closes the processing liquid flow path. This allows suck back and prevention of drips of the processing liquid. Moreover, the controller causes the valve element drive unit to move the valve element for regulating the flow rate of the processing liquid when the on-off valve opens the processing liquid flow path. Accordingly, this allows the valve element drive unit to perform the flow regulation of the processing liquid readily that is current1y controlled with an operator's sense. Moreover, since prevention of the drips of the processing liquid as well as the flow regulation of the processing liquid are performable with the same valve element drive unit, the needless configuration is omittable to achieve space saving compared to the configuration in which the valve element drive unit is provided individually. This allows supply of the processing liquid at different flow rates to every substrate, and the flow rate of the processing liquid is variable to the same substrate in the course of the supply.

Moreover, it is preferred that the valve element drive unit of the processing liquid supplying apparatus is a motor. The motor as the valve element drive unit allows easy suck back at plural times, i.e., in multiple stages. This also achieves ready variation in valve element position for the flow regulation.

It is also preferred that the controller of the processing liquid supplying apparatus causes the valve element drive unit to move the valve element to a suck back reference position for decreasing the flow rate of the processing liquid, and then causes the on-off valve to close the processing liquid flow path and causes the valve element drive unit to move the volume variation unit cooperating with the valve element for increasing the volume of the processing liquid flow path. This decreases the flow rate of the processing liquid when the on-off valve closes the processing liquid flow path, leading to prevention of drips of the processing liquid caused by the increased flow rate of the processing liquid. That is, this certainly allows prevention of the drips.

Moreover, it is preferred that the controller of the processing liquid supplying apparatus causes the valve element drive unit to move the valve element from a position of the valve element with the increased volume of the downstream processing liquid flow path to a position where the flow rate is changed to a preset flow rate and causes the on-off valve to open the processing liquid flow path. Although the position of the valve element is shifted by the suck back, the preset flow rate of the processing liquid is able to be supplied upon opening of the processing liquid flow path with the on-off valve.

In the aspect of the processing liquid supplying apparatus, the valve element is moved upward to the position where the flow rate is changed to the preset flow rate when the on-off valve opens the processing liquid flow path. Since the valve element is moved upward for the preset flow rate upon the opening of the processing liquid flow path with the on-off valve, no processing liquid is pushed out and further suck back is performed. This avoids liquid drips.

In the aspect of the processing liquid supplying apparatus, a lowering speed of the valve element is changed in such a manner that the flow rate is changed to the preset flow rate when the valve element drive unit causes the valve element to move downwardly to the position where the flow rate is changed to the preset flow rate. For instance, the lowering speed of the valve element is changed such that the dispensing nozzle dispenses the processing liquid at the preset flow rate when the valve element is moved downward to a position where the flow rate is changed to the preset flow rate. This allows the flow rate of the processing liquid dispensed by the movement of the valve element to approach to a flow rate at which the on-off valve opens the processing liquid flow path.

It is also preferred that the processing liquid flow path of the processing liquid supplying apparatus is formed by a single part. This achieves integration of the on-off valve and the suck back valve with a flow rate regulation function, leading to a simplified configuration.

Moreover, the processing liquid supplying apparatus according to the aspect further includes a dispensing nozzle disposed downstream of the valve element, the dispensing nozzle being connected to the processing liquid flow path via a pipe for dispensing the processing liquid. This allows suction of the processing liquid within the dispensing nozzle and flow regulation of the processing liquid dispensed from the dispensing nozzle.

Moreover, in the processing liquid supplying apparatus according to the aspect, the processing liquid is a developer. This avoids drips of the developer, leading to flow regulation of the developer.

Moreover, in the processing liquid supplying apparatus according to the aspect, the controller causes the valve element drive unit to reciprocate the volume variation unit cooperating with the valve element when the on-off valve closes the processing liquid flow path. For instance, a tip of the dispensing nozzle for dispensing the developer as the processing liquid is immersed into deionized water for sucking the deionized water, holding the sucked deionized water for a certain period of time, or pushing out the sucked deionized water, whereby the tip end of the dispensing nozzle is cleaned.

Another aspect of the present invention provides a method of controlling a processing liquid supplying apparatus including a processing liquid flow path that passes a processing liquid, an on-off valve that opens/closes the processing liquid flow path, a valve element disposed downstream of the on-off valve for adjusting an aperture of the processing liquid flow path, a volume variation unit disposed downstream of the on-off valve for varying a volume of a downstream processing liquid flow path disposed downstream of the on-off valve, and a valve element drive unit that drives the valve element. The method includes a step of increasing the volume of the downstream processing liquid flow path by causing the valve element drive unit to move the volume variation unit cooperating with the valve element when the on-off valve closes the processing liquid flow path, and a step of regulating a flow rate of the processing liquid by causing the valve element drive unit to move the valve element when the on-off valve opens the processing liquid flow path.

According to the processing liquid supplying apparatus according to the other aspect of present invention, downstream of the on-off valve that opens/closes the processing liquid flow path, provided are the valve element that adjusts the aperture of the processing liquid flow path, and the volume variation unit that cooperates with the valve element for varying the volume of the downstream processing liquid flow path disposed downstream of the on-off valve. The valve element drive unit drives the valve element. Such control achieves the increased volume of the downstream processing liquid flow path by causing the valve element drive unit to move the volume variation unit cooperating with the valve element when the on-off valve closes the processing liquid flow path. Accordingly, this allows suck back, leading to prevention of drips of the processing liquid. In addition, the control obtains the regulated flow rate of the processing liquid by causing the valve element drive unit to move the valve element when the on-off valve opens the processing liquid flow path. This facilitates the flow regulation of the processing liquid by the valve element drive unit which is current1y made by the operator's sense. Moreover, since prevention of the drips of the processing liquid as well as the flow regulation of the processing liquid are performable with the same valve element drive unit, the needless configuration is omittable to achieve space saving compared to the configuration in which the valve element drive unit is provided individually. This allows supply of the processing liquid at different flow rates to every substrate, and the flow rate of the processing liquid is variable to the same substrate in the course of the supply.

### Advantageous Effects of Invention

According to the processing liquid supplying apparatus and the method of controlling the processing liquid supplying apparatus according to the aspects of present invention, downstream of the on-off valve that opens/closes the processing liquid flow path, provided are the valve element that adjusts the aperture of the processing liquid flow path, and the volume variation unit that cooperates with the valve element for varying the volume of the downstream processing liquid flow path disposed downstream of the on-off valve. The valve element drive unit drives the valve element. Such control achieves the increased volume of the downstream processing liquid flow path by causing the valve element drive unit to move the volume variation unit cooperating with the valve element when the on-off valve closes the processing liquid flow path. Accordingly, this allows suck back, leading to prevention of drips of the processing liquid. In addition, the control obtains the regulated flow rate of the processing liquid by causing the valve element drive unit to move the valve element when the on-off valve opens the processing liquid flow path. This facilitates the flow regulation of the processing liquid by the valve element drive unit which is current1y made by the operator's sense. Moreover, since prevention of the drips of the processing liquid as well as the flow regulation of the processing liquid are performable with the same valve element drive unit, the needless configuration is omittable to achieve space saving compared to the configuration in which the valve element drive unit is provided individually.

Moreover, such control causes the valve element drive unit to move the valve element to a suck back reference position for decreasing the flow rate of the processing liquid, and then causes the on-off valve to close the processing liquid flow path, and causes the valve element drive unit to move the volume variation unit cooperating with the valve element for increasing the volume of the processing liquid flow path. This decreases the flow rate of the processing liquid when the on-off valve closes the processing liquid flow path, leading to prevention of the drips of the processing liquid caused by the increased flow rate of the processing liquid. That is, this certainly allows prevention of the drips.

### BRIEF DESCRIPTION OF DRAWINGS

FIG. 1 is a block diagram schematically illustrating a substrate treating apparatus according to one embodiment.

FIG. 2 is a longitudinal sectional view of an on-off valve and a suck back valve with a flow rate regulating function.

FIG. 3 is a timing chart illustrating operation of the on-off valve and the suck back valve with the flow rate regulating function.

FIG. 4(a) illustrates operation of the processing liquid supplying unit and a position of the dispensing nozzle relative to a substrate, FIG. 4(b) illustrates one example of a dispensation amount (flow rate) in a position relationship of FIG. 4(a), and FIG. 4(c) illustrates another example of the dispensation amount (flow rate) in the position relationship of FIG. 4(a).

FIG. 5 is a timing chart illustrating operation of an on-off valve and a suck back valve with a flow rate regulating function according to one modification.

FIG. 6 is a longitudinal sectional view of the on-off valve and the suck back valve with the flow rate regulating function according to the modification.

FIG. 7 illustrates operation of a processing liquid supplying unit according to the modification.

FIG. 8 is a block diagram schematically illustrates a current1y-used processing liquid supplying apparatus.

### DESCRIPTION OF EMBODIMENTS

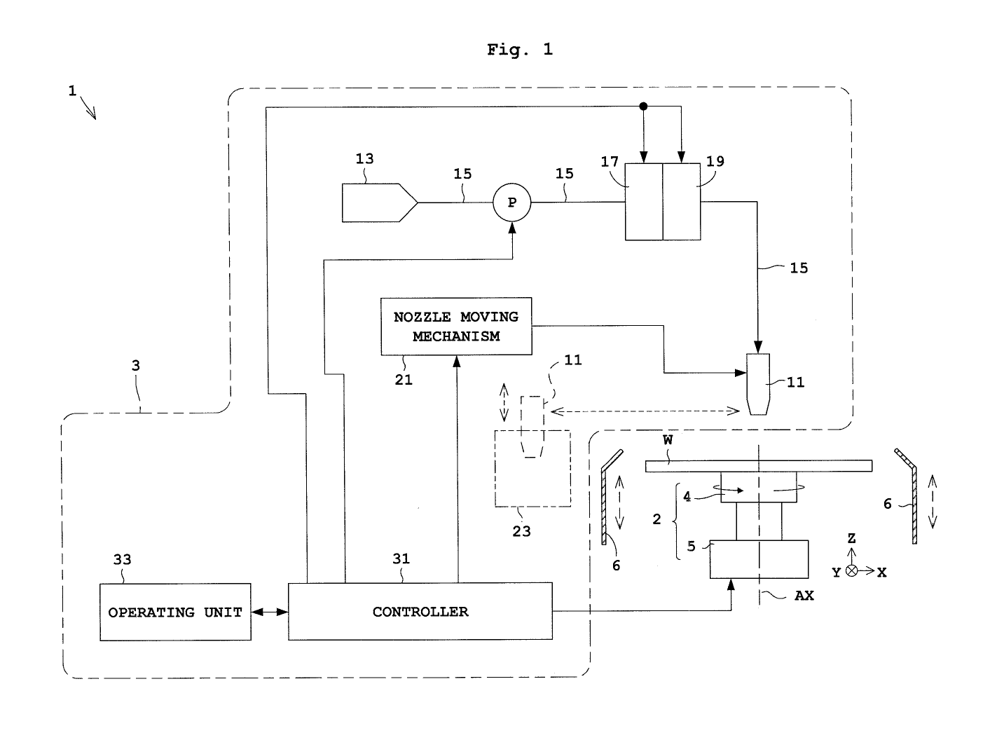

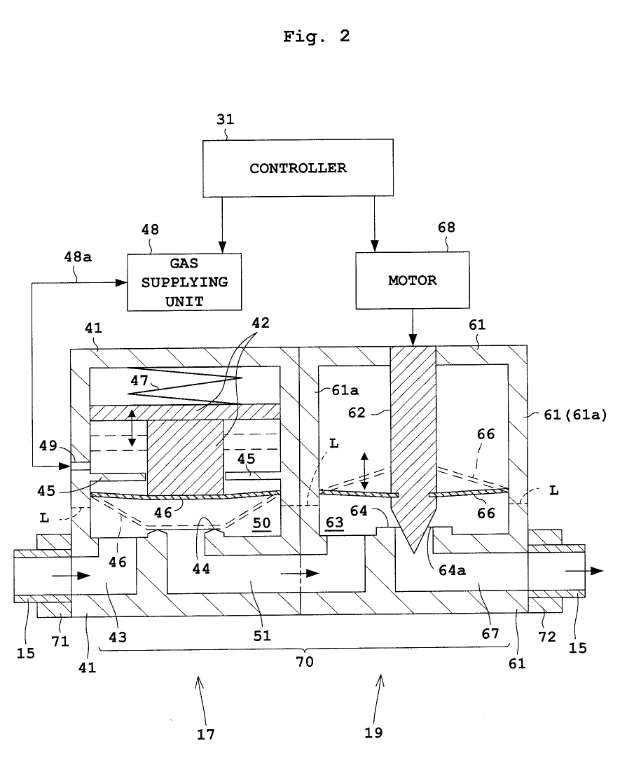

The following describes embodiments of the present invention with reference to drawings. FIG. 1 is a block diagram schematically illustrating a substrate treating apparatus according to one embodiment. FIG. 2 is a longitudinal sectional view of an on-off valve and a suck back valve having a flow rate regulating function.

<Configuration of Substrate Treating Apparatus 1>Reference is made to FIG. 1. A substrate treating apparatus 1 includes a holding rotator 2 that holds and rotates a substrate W in a substantially horizontal attitude, and a processing liquid supplying unit 3 that supplies a processing liquid. Examples of the processing liquid used include a coating liquid such as a photoresist, a developer, a solvent, or a rinse liquid such as deionized water. Here, the processing liquid supplying unit 3 corresponds to the processing liquid supplying apparatus in the present invention.

The holding rotator 2 includes a spin chuck 4 that holds a rear face of the substrate W through vacuum-suction, and a rotation drive unit 5 that is composed of a motor and the like for rotating the spin chuck 4 around a rotary shaft AX in a substantially vertical direction. A cup 6 that is movable upwardly/downwardly is disposed around the holding rotator 2 so as to surround a lateral side of the substrate W.

The processing liquid supplying unit 3 includes a dispensing nozzle 11 that dispenses the processing liquid to the substrate W, a processing liquid supplying source 13 composed of a tank and the like for storing the processing liquid, and a processing liquid pipe 15 that feeds the processing liquid from the processing liquid supplying source 13 to the dispensing nozzle 11. A pump P, an on-off valve 17, and a suck back valve 19 having a flow rate regulating function rate are interposingly arranged on the processing liquid pipe 15 in this order from the processing liquid supplying source 13. It should be noted that another element may be interposingly arranged on the processing liquid pipe 15. For instance, a filter, not shown, may be interposingly arranged between the pump P and the on-off valve 17. Here, the processing liquid pipe 15 corresponds to the pipe in the present invention.

A nozzle moving mechanism 21 causes the dispensing nozzle 11 to move between a standby pot 23 outside the substrate W and a dispensing position above the substrate W. The nozzle moving mechanism 21 is composed of a holder arm, a motor, and the like. Here, the dispensing nozzle 11 is disposed downstream of the suck back valve 19, and is connected to a processing liquid flow path 70 mentioned later via the processing liquid pipe 15.

The pump P feeds out the processing liquid to the dispensing nozzle 11. The on-off valve 17 performs supply and stops the supply of the processing liquid. The suck back valve 19 is combined with the on-off valve 17 to suck back the processing liquid and regulate a flow rate of the processing liquid. The on-off valve 17 and the suck back valve 19 are described later in detail. It should be noted that the suck back valve 19 having the flow rate regulating function is also referred to as a flow regulating valve having a suck back function.

The processing liquid supplying unit 3 includes a controller 31 composed of a central processing unit (CPU) and the like, and an operating unit 33 for operating the substrate treating apparatus 1. The controller 31 controls each element of the substrate treating apparatus 1. The operating unit 33 includes a display unit such as a liquid crystal monitor, a memory unit such as a ROM (Read-only Memory), a RAM (Random-Access Memory), and a hard disk, and an input unit such as a keyboard, a mouse, and various types of buttons. The memory unit stores various conditions for controlling the on-off valve 17 and the suck back valve 19, and other conditions for substrate treatment.

<On-Off Valve 17 and Suck Back Valve 19 with Flow-Rate Regulating Function>

The following describes detailed configurations of the on-off valve 17 and the suck back valve 19. Reference is made to FIG. 2. The on-off valve 17 opens/closes a processing liquid flow path 70 composed of an upstream flow path 43, an on-off chamber internal flow path 50, a coupling flow path 51, a valve chamber internal flow path 63, and a downstream flow path 67, which are to be mentioned later. The suck back valve 19 sucks back the processing liquid in combination with the operation of the on-off valve 17, and regulates the flow rate of the processing liquid.

<Configuration of On-Off Valve 17>

The on-off valve 17 is disposed in the course of the processing liquid pipe 15, and is composed of the upstream flow path 43, the on-off chamber internal flow path 50 of an on-off chamber 41, and the coupling flow path 51 in communication with the valve chamber 61 of the suck back valve 19 which are connected to one another in series. The processing liquid pipe 15 is attached to the on-off chamber 41 via an upstream joint 71, and is in fluid communication with the upstream flow path 43 of the on-off valve 17. The on-off valve 17 performs switching of flow of the processing liquid between a circulation state and a blocked state in the on-off chamber 41 by on-off operation, which is to be mentioned later.

A first end of the upstream flow path 43 is in communication with a bottom of the on-off chamber internal flow path 50 of the on-off chamber 41. Here, a second end of the processing liquid pipe 15 is connected to the pump P. Accordingly, the processing liquid fed out through the pump P passes through the upstream flow path 43 into the on-off chamber internal flow path 50 of the on-off chamber 41.

The on-off chamber 41 is a hollow box, and includes inside thereof a piston 42, a spring 47, a partition 45, and a diaphragm 46 as the valve element. The piston 42 is slidably disposed within the on-off chamber 41 in a vertical direction of the drawing. The spring 47 is disposed between a top face of the piston 42 and an upper inner wall of the on-off chamber 41.

The partition 45 is a flat plate member that divides the interior of the on-off chamber 41 vertically, and the center thereof is passed through by the piston 42. A contact portion between the piston 42 and the partition 45 is completely sealed although the piston 42 is slidably relative to the partition 45. Accordingly, when air is blown into the on-off chamber 41 through a gas pipe 48a , the air does not leak below the partition 45 (adjacent to the diaphragm 46).

A periphery edge of the diaphragm 46 is fixed to an inner wall of the on-off chamber 41. The center of the diaphragm 46 is fixed to a lower end of the piston 42.

A first valve seat 44 is disposed at the center of the bottom of the on-off chamber internal flow path 50 in the on-off chamber 41. The coupling flow path 51 provides communication between the first valve seat 44 of the on-off chamber 41 and a valve chamber internal flow path 63 in the valve chamber 61 of the suck back valve 19 to be mentioned later.

An intake and exhaust port 49 for performing intake and exhaust of gas from a gas supplying unit 48 is disposed on a side wall of the on-off chamber 41. The gas supplying unit 48 is controlled by the controller 31. The gas supplying unit 48 is composed of a gas supplying source, a gas on-off valve, a speed controller (each not shown) and the like. The controller 31 performs control so as to cause the gas supplying unit 48 to supply gas to the intake and exhaust port 49 through the gas pipe 48a and to exhaust gas through the intake and exhaust port 49.

With the configuration of the on-off valve 17 mentioned above, when the gas supplying unit 48 supplies the gas into the on-off chamber 41 through the intake and exhaust port 49, the piston 42 is pressed upward against an elastic force of the spring 47 (under the condition as illustrated by solid lines in FIG. 2). When the piston 42 is pressed upwardly, the diaphragm 46 fixed thereto is deformed to be remote from the first valve seat 44.

As illustrated by the solid lines in FIG. 2, when the diaphragm 46 as the valve element is remote from the first valve seat 44, communication is provided among the upstream flow path 43, the on-off chamber internal flow path 50, and the coupling flow path 51. Then, the processing liquid fed out from the pump P passes from the upstream flow path 43 through the on-off chamber internal flow path 50, the coupling flow path 51, a valve chamber internal flow path 63 mentioned later, and the downstream flow path 67 into the dispensing nozzle 11, and accordingly, the processing liquid is dispensed from the dispensing nozzle 11 to the substrate W. In other words, the condition illustrated by the solid lines in FIG. 2 corresponds to the condition in which the processing liquid flow path 70 are opened to pass the processing liquid. That is, the above corresponds to the condition (opened condition) where the on-off valve 17 opens the processing liquid flow path 70.

In contrast to this, when the gas supplying unit 48 exhausts gas within the on-off chamber 41 through the intake and exhaust port 49, pressure within the on-off chamber 41 decreases, and thus no pressure exists that presses the piston 42 upwardly against the restoring force of the spring 47. Accordingly, the piston 42 is pressed downwardly by the restoring force of the spring 47 as illustrated by dotted lines in FIG. 2. When the piston 42 is pressed downwardly, the diaphragm 46 fixed thereto is deformed as illustrated by the dotted lines in FIG. 2 to be sealed tight1y with the first valve seat 44.

As illustrated in FIG. 2, when the diaphragm 46 as the valve element is tight1y sealed with the first valve seat 44, an unblocked condition is provided between the on-off chamber flow path 50 and the coupling flow path 51. Accordingly, the processing liquid fed out from the pump P is not able to flow toward the coupling flow path 51, and thus the processing liquid stops flowing. That is, the above leads to the condition where the processing liquid flow path 70 is blocked by the on-off valve 17 (a closed condition).

As mentioned above, the gas supplying unit 48 functions as an actuating device of actuating the diaphragm 46 as the valve element by the piston 42, the spring 47, and the like.

<Configuration of Suck Back Valve 19 with Flow-Rate Regulating Function>

As illustrated in FIG. 2, the suck back valve 19 is disposed downstream of the on-off valve 17. The suck back valve 19 includes a valve chamber 61 as a hollow box member, a needle 62 that is movable upwardly/downwardly in FIG. 2 within the valve chamber 61, and a downstream flow path 67.

The valve chamber internal flow path 63 is disposed within the valve chamber 61 for passing the processing liquid. In addition, a second valve seat 64 for receiving the needle 62 is disposed at the center of the bottom of the valve chamber internal flow path 63 in the valve chamber 61. An opening 64a is provided in the second valve seat 64 for passing the processing liquid. The opening 64a is in communication with the downstream flow path 67. The processing liquid pipe 15 is attached to the valve chamber 61 via a downstream joint 72, and thus in fluid communication with the downstream flow path 67 of the suck back valve 19. When the second valve seat 64 receives the needle 62, the needle 62 blocks the opening 64a. This achieves closure of a flow path between the valve chamber internal flow path 63 and the downstream flow path.

The needle 62 is configured to adjust a width of the flow path (an aperture of the opening 64a) provided between the valve chamber internal flow path 63 and the downstream flow path 67, i.e., an aperture of the processing liquid flow path 70. In other words, the needle 62 adjusts a clearance to the opening 64a of the second valve seat 64, thereby regulating a flow rate of the processing liquid that passes through the clearance.

Moreover, the suck back valve 19 includes a diaphragm 66 that is attached to a tip portion of the needle 62 and a motor (electric motor) 68 that drives the needle 62 upwardly/downwardly in FIG. 2. A periphery edge of the diaphragm 66 is fixed to a side wall 61a of the valve chamber 61, and the diaphragm 66 divides the interior of the valve chamber 61 across a moving direction of the needle 62.

In addition, the diaphragm 66 cooperates with the needle 62 as in FIG. 2. This allows the diaphragm 66 to vary the volume of the flow path from the coupling flow path 51 downstream of the on-off valve 17 via the valve chamber internal flow path 63 to the downstream flow path 67. In other words, movement of the needle 62 allows adjustment in clearance to the second valve seat 64 and variation in volume of the flow path from the coupling flow path 51 via the valve chamber internal flow path 63 to the downstream flow path 67 simultaneously.

Here, the needle 62 corresponds to the valve element in the present invention. The diaphragm 66 corresponds to the volume variation unit in the present invention. Moreover, the motor 68 corresponds to the valve element drive unit in the present invention.

The controller 31 controls the motor 68 by a given number of pulse, for example. A mechanism not shown converts rotation of the motor 68 to apply an upward/downward driving force to the needle 62. For instance, the controller 31 causes the motor 68 to move the diaphragm 66 cooperating with the needle 62 when the on-off valve 17 is closed, thereby increasing the volume of the flow path for suck back from the coupling flow path 51 via the valve chamber internal flow path 63 to the downstream flow path 67. Moreover, the controller 31 causes the motor 68 to move the needle 62 when the on-off valve 17 is opened for regulating the flow rate of the processing liquid. Moreover, it is preferred that a sensor such as a rotary encoder, not shown, is attached to the motor 68 for obtaining an accurate moving amount of the needle 62 in the upward/downward direction.

In addition, the on-off valve 17 is disposed adjoining the suck back valve 19. Accordingly, the on-off valve 17 is integrated with the suck back valve 19 for achieving a simplified configuration. Moreover, the upstream flow path 43 of the on-off valve 17, the downstream flow path 67 of the suck back valve 19, and the coupling flow path 51 connecting the on-off chamber internal flow path 50 and the valve chamber internal flow path 63 are formed as a single part. In this case, the on-off chamber 41 and the valve chamber 61 may be partially formed as a single part as the on-off chamber 41 and the valve chamber 61 illustrated below the dotted lines L in FIG. 2.

Moreover, the upstream flow path 43, the on-off chamber internal flow path 50, the coupling flow path 51, the valve chamber internal flow path 63, and the downstream flow path 67 form the processing liquid flow path 70 that passes the processing liquid. Here, the coupling flow path 51, the valve chamber internal flow path 63, and the downstream flow path 67 correspond to the downstream processing liquid flow path in the present invention.

<Operation of Substrate Treating Apparatus 1>

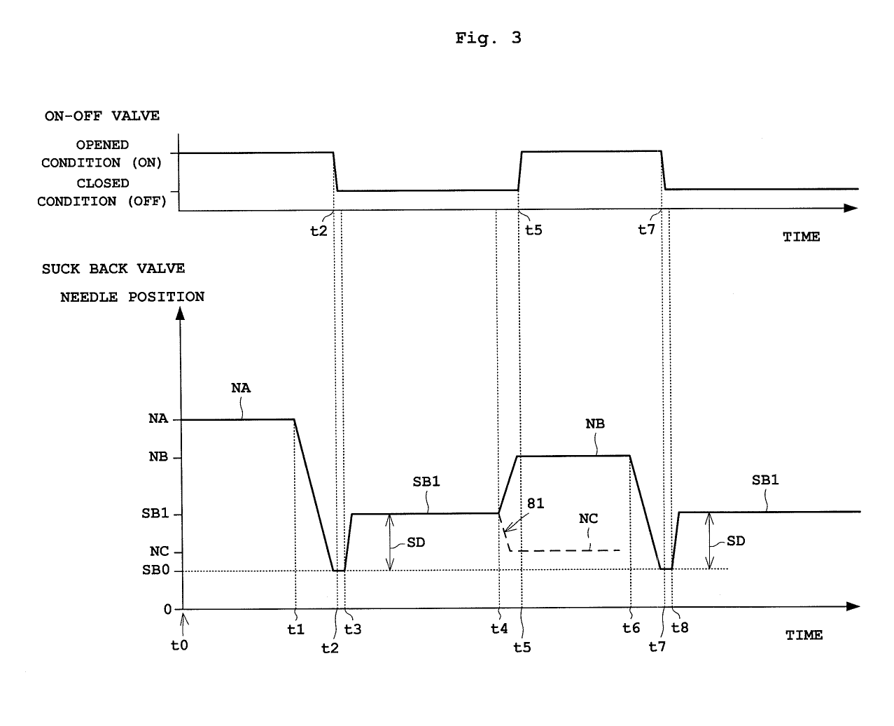

The following describes operation of the substrate treating apparatus 1, especially operation of the processing liquid supplying unit 3. FIG. 3 is a timing chart illustrating operation of the on-off valve 17 and the suck back valve 19 having a flow-rate regulating function. The controller 31 controls each element of the substrate treating apparatus 1 in accordance with dispensing conditions (recipes) set in advance.

With the embodiment of the present invention, the motor 68 of the suck back valve 19 moves the needle 62 in response to opening/closing of the on-off valve 17 to perform suck back (drip prevention) and flow regulation of the processing liquid. At this time, the suck back leads to irregular flow regulation, whereas the flow regulation leads to irregular suck back. In the embodiment of the present invention, operation is performed in consideration with this point.

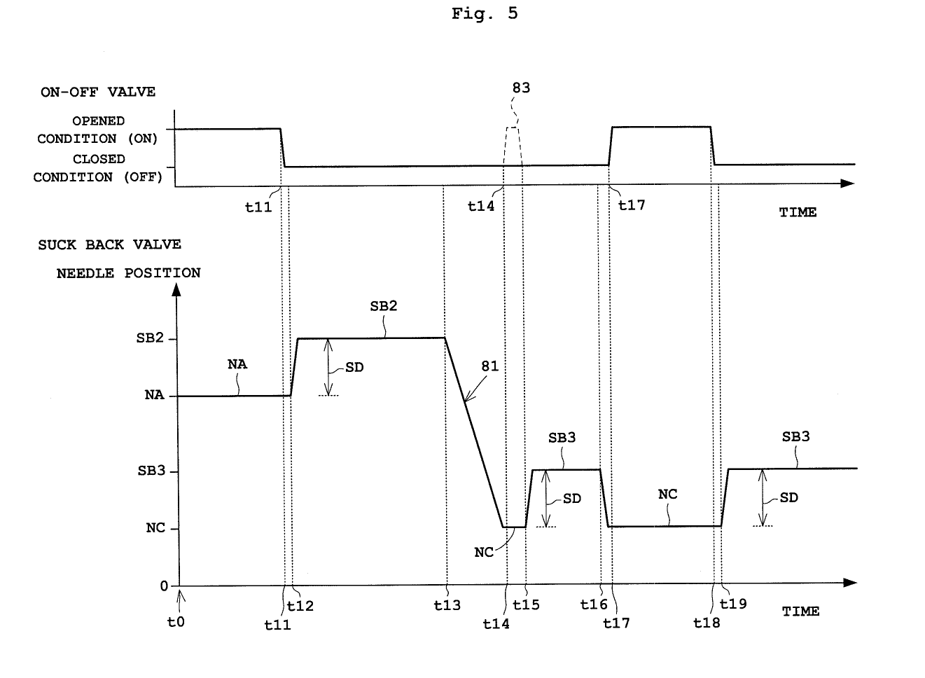

In the suck back valve 19, the motor 68 performs upward/downward movement of the needle 62. Here, the upward movement corresponds to remote movement of the needle 62 from the second valve seat 64. The downward movement corresponds to approach of the needle 62 to the second valve seat 64. Moreover, in FIGS. 3 and 5 mentioned later, the position “0” of the needle 62 is the position where the needle 62 moves closest to the second valve seat 64 regardless of flow of the processing liquid.

First1y, in the substrate treating apparatus 1 of FIG. 1, a transport mechanism not shown transports the substrate W to the holding rotator 2. The holding rotator 2 holds the rear face of the substrate W, and rotates the held substrate W. The nozzle moving mechanism 21 moves the dispensing nozzle 11 from the standby pot 23 outside the substrate W to the dispensing position above the substrate W. The controller 31 performs control to the on-off valve 17 and the suck back valve 19 to dispense the processing liquid from the dispensing nozzle 11. Here, the pump P is driven. When the on-off valve 17 is opened, the processing liquid stored in the processing liquid supplying source 13 is dispensed from the dispensing nozzle 11.

At time t0 in FIG. 3, the on-off valve 17 is opened and the processing liquid is dispensed from the dispensing nozzle 11. In addition, in the suck back valve 19, the motor 68 causes the needle 62 to move to a position NA while the on-off valve 17 is opened, thereby regulating the flow rate of the processing liquid corresponding to the position NA.

The controller 31 performs control to decrease the flow rate to certainly avoid drips before the on-off valve 17 is closed when the dispensing nozzle 11 stops dispensation of the processing liquid. Specifically, the controller 31 causes the motor 68 to move the needle 62 to a suck back reference position SB0 for decreasing the flow rate of the processing liquid at time t1. Thereafter, the controller 31 causes the on-off valve 17 to close the flow path between the on-off chamber internal flow path 50 of the processing liquid flow path 70 and the coupling flow path 51 at time t2.

Moreover, the controller 31 causes the motor 68 to move the needle 62 to a suck back executable position SB1 at time t3. In other words, the controller 31 causes the motor 68 to move the diaphragm 66 cooperating with the needle 62 for increasing a volume of the flow path from the coupling flow path 51 via the valve chamber internal flow path 63 to the downstream flow path 67. This allows suck back (suction) of the processing liquid within the tip end of the dispensing nozzle 11. It should be noted that the time t2 may be the same timing as the time t3. Alternatively, the time t2 may be delayed a litt1e from the time t3. In addition, the suck back includes a set moving amount SD of the needle 62. The moving amount SD may be constant, or may be varied.

After dispensation of the processing liquid to the substrate W is finished, the substrate W on the holding rotator 2 is replaced. Specifically, the holding rotator 2 in FIG. 1 stops rotation of the substrate W, and releases the holding of the substrate W. The nozzle moving mechanism 21 causes the dispensing nozzle 11 to move to the standby pot 23 outside the substrate W. Then, the transport mechanism not shown replaces the substrate W. As noted above, the holding rotator 2 holds the rear face of the substrate W, and rotates the held substrate W. In addition, the nozzle moving mechanism 21 moves the dispensing nozzle 11 from the standby pot 23 outside the substrate W to the dispensing position above the substrate W.

The processing liquid is again dispensed from the dispensing nozzle 11. The suck back causes the needle 62 to move depending on the configuration of the suck back valve 19 in the present invention. Movement of the needle 62 needs another flow regulation. The controller 31 causes the motor 68 to move the needle 62 from the suck back executable position SB1 of the needle 62 while the volume of the flow path is increased from the coupling flow path 51 through the valve chamber internal flow path 63 to the downstream flow path 67 at time t4, and then to open the on-off valve 17 at time t5.

The following describes two examples of controlling operation at the time t4. Here, the two examples of controlling operation correspond to upward movement to a position NB and downward movement to a position NC.

First1y, the case is to be described where the needle 62 is moved upwardly from the suck back executable position SB1 to the position NB. The controller 31 causes the motor 68 to move the needle 62 from the suck back executable position SB1 to the position NB at the time t4. The diaphragm 66 cooperating with the needle 62 moves upward in synchronization with the upward movement of the needle 62. Accordingly, further suck back is to be performed. Under such a condition, the controller 31 causes the on-off valve 17 to open the processing liquid flow path 70 for dispensing the processing liquid from the dispensing nozzle 11 at the time t5. Since the needle 62 is moved upward from the suck back executable position SB1 when the on-off valve 17 opens the processing liquid flow path 70, no processing liquid is pushed out from the dispensing nozzle 11 to achieve further suck back. This clears possibility of drips.

The following describes downward movement of the needle 62 from the suck back executable position SB1 to the position NC. The controller 31 causes the motor 68 to move the needle 62 at the time t4 from the suck back executable position SB1 to the position NC. Downward movement of the needle 62 pushes out the processing liquid. Accordingly, the processing liquid may be dispensed from the dispensing nozzle 11 depending on the downward movement amount of the needle 62.

Then, the controller 31 causes the motor 68 to change a moving speed of the needle 62 so as to obtain a preset flow rate F when the needle 62 is moved downward to the position NC where the flow rate is changed to the preset low rate F. That is, a lowering speed of the needle 62 (see gradient 81 in FIG. 3) is adjusted in such a manner that the processing liquid is pushed out at the flow rate F equal to or close to the flow rate F at the position NC of the needle 62. Subsequent1y, the controller 31 causes the on-off valve 17 to open the processing liquid flow path 70 at the time t5 for dispensing the processing liquid from the dispensing nozzle 11. Since the lowering speed of the needle 62 is adjusted and subsequent1y the on-off valve 17 is turned opened, the processing liquid is able to flow naturally and successively at the preset flow rate F.

After the processing liquid is dispensed from the dispensing nozzle 11 for a given period of time, the needle 62 of the suck back valve 19 is moved downwardly to the suck back reference position SB0 at the time t6 to decrease the flow rate. Thereafter, the on-off valve 17 is turned closed at time t7. Then, the needle 62 of the suck back valve 19 is moved upwardly to the suck back executable position SB1 at time t8 to move the diaphragm 66 cooperating with the needle 62 upwardly for suck back.

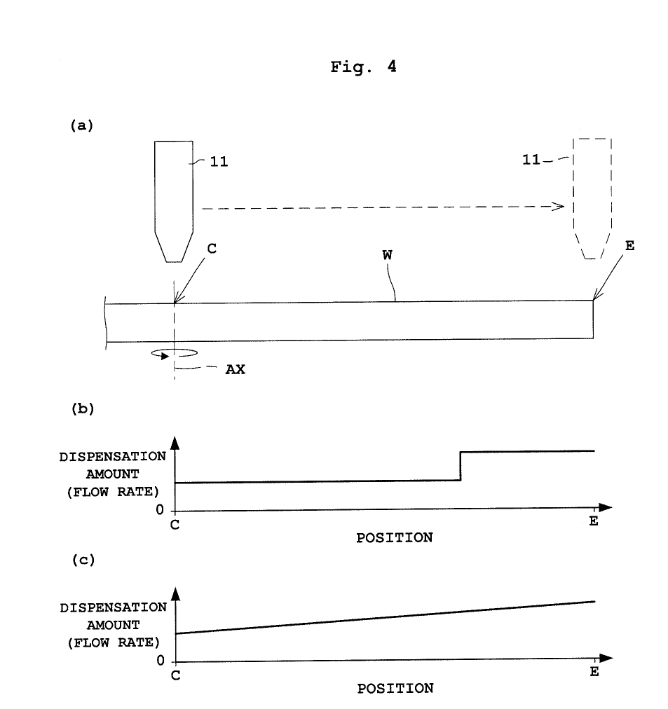

The following describes the case where a dispensation rate is changed within the same substrate W with reference to FIGS. 4(a) to 4(c). With the present invention, as in the position NA and the position NB in FIG. 3, the flow regulation is readily performable to every different substrate W or every set of substrates when the substrates are prepared in sets. In addition, the flow regulation within the same substrate W is readily performable.

FIG. 4(a) illustrates a position of the dispensing nozzle 11 relative to the substrate W. FIGS. 4(b) and 4(c) each illustrate one example of a dispensation amount (flow rate) in the positional relationship of FIG. 4(a). There may be the case where the nozzle moving mechanism 21 causes the dispensing nozzle 11 to move from the center C of the substrate W to an edge E of the substrate W while the dispensing nozzle 11 dispenses the processing liquid. In such a case, a dispensation amount may be increased to a width of 50 mm from the edge E, for example, as in FIG. 4(b). Alternatively, the amount may be decreased if necessary. Alternatively, the processing liquid may be dispensed from the dispensing nozzle 11 at the flow rate with the gradient as in FIG. 4(c).

With the present embodiment, provided downstream of the on-off valve 17 that opens/closes the processing liquid flow path 70 are the needle 62 that adjusts the width of the flow path (aperture of the opening 64a) formed between the valve chamber internal flow path 63 and the downstream flow path 67, and the diaphragm 66 that cooperates with the needle 62 and changes the volume of the flow path from the coupling flow path 51 downstream of the on-off valve 17 via the valve chamber internal flow path 63 to the downstream flow path 67. The motor 68 drives the needle 62. The controller 31 causes the motor 68 to move the diaphragm 66 cooperating with the needle 62 for increasing the volume of the flow path from the coupling flow path 51 via the valve chamber internal flow path 63 to the downstream flow path 67 when the on-off valve 17 closes the processing liquid flow path 70. Accordingly, this allows suck back, leading to prevention of drips of the processing liquid. In addition, the controller 31 causes the motor 68 to move the needle 62 for regulating the flow rate of the processing liquid when the on-off valve 17 opens the processing liquid flow path 70. This facilitates the flow regulation of the processing liquid by the motor 68 which is current1y made by the operator's sense. Moreover, since prevention of the drips of the processing liquid as well as the flow regulation of the processing liquid are performable with the same motor 68, a needless configuration is omittable to achieve space saving compared to the configuration in which the motor 68 is provided individually. This allows supply of the processing liquid at different flow rates to every substrate W, and the flow rate of the processing liquid is variable to the same substrate W in the course of the supply.

Moreover, with the present embodiment, the on-off valve 17 is primarily used for opening/closing, and the suck back valve 19 performs fine adjustment. Accordingly, the on-off valve 17 with the simplified configuration is selectable.

Moreover, the motor 68 moves the needle 62 of the suck back valve 19, leading to easy suck back at plural times, i.e., in multiple stages. This also achieves ready variation in position of the needle 62 for the flow regulation.

Moreover, the controller 31 causes the motor 68 to move the needle 62 to the suck back reference position SB0 for decreasing the flow rate of the processing liquid, and thereafter causes the on-off valve 17 to close the processing liquid flow path 70 and causes the motor 68 to move the diaphragm 66 cooperating with the needle 62 for increasing the volume of the processing liquid flow path 70. Accordingly, the flow rate of the processing liquid becomes decreased when the on-off valve 17 closes the processing liquid flow path 70, leading to suppressed drips of the processing liquid caused by the increased flow rate of the processing liquid. That is, this certainly allows prevention of the dripping.

Moreover, the controller 31 causes the motor 68 to move the needle 62 from the position of the needle 62 where the volume of the flow path increases from the coupling flow path 51 via the valve chamber internal flow path 63 to the downstream flow path 67 to a position at which the flow rate is changed to the preset flow rate, and causes the on-off valve 17 to open the processing liquid flow path 70. Although the position of the needle 62 is changed by the suck back, the preset flow rate of the processing liquid is able to be supplied upon opening of the processing liquid flow path 70 with the on-off valve 17.

Moreover, the needle 62 is moved upwardly to the position where the flow rate is changed to the preset flow rate upon the opening of the processing liquid flow path 70 with the on-off valve 17. Since the needle 62 is moved upwardly for the preset flow rate upon the opening of the processing liquid flow path 70 with the on-off valve 17, no processing liquid is pushed out and further suck back is performed. This clears possibility of liquid drips.

Moreover, the lowering speed (see the gradient 81 in FIG. 3) of the needle 62 is changed such that the flow rate is changed to the preset flow rate when the motor 68 causes the needle 62 to move downward to a position where the flow rate is changed to the preset flow rate. For instance, the lowering speed of the needle 62 is changed such that the dispensing nozzle 11 dispenses the processing liquid at the preset flow rate when the needle 62 is moved downwardly to a position where the flow rate is changed to the preset flow rate. This allows the flow rate of the processing liquid dispensed by the movement of the needle 62 to approach to a flow rate at which the on-off valve 17 opens the processing liquid flow path 70.

Moreover, the processing liquid supplying apparatus 3 further includes the dispensing nozzle 11 downstream of the needle 62, the dispensing nozzle 11 being connected to the processing liquid flow path 70 via the processing liquid pipe 15 for dispensing the processing liquid. This allows suction of the processing liquid within the dispensing nozzle 11 for flow regulation of the processing liquid dispensed from the dispensing nozzle 11.

The present invention is not limited to the foregoing examples, but may be modified as follows.

(1) In the embodiments mentioned above, the needle 62 of the suck back valve 19 is moved downwardly to the suck back reference position SB0 before the on-off valve 17 is turned off as at the time t1 in FIG. 3. In contrast to this, the on-off valve 17 may be turned off without the movement of the needle 62 when the downward movement to the suck back reference position SB0 is not needed.

The on-off valve 17 is turned off at the time til in FIG. 5 without the downward movement of the needle 62 of the suck back valve 19 at the position NA. The needle 62 is moved upwardly to the position SB2 by a preset moving amount SD at the time t12. That is, the diaphragm 66 cooperating with the needle 62 is moved upwardly for suck back. After the substrate W is replaced, the dispensing nozzle 11 again dispenses the processing liquid while the needle 62 is disposed at the position NC lower than the position NA.

The following describes the example of the operation in this case. The nozzle moving mechanism 21 moves the dispensing nozzle 11 to the standby pot 23. Under such a condition, the needle 62 is moved downwardly to a position NC at time t13. At this time, the processing liquid pushed out from the dispensing nozzle 11 is collected within the standby pot 23. Then, the needle 62 is moved upwardly by the moving amount SD to the position SB3. That is, the diaphragm 66 cooperating with the needle 62 performs suck back. It should be noted that dummy dispensation of the processing liquid may be made while the on-off valve 17 is turned on as illustrated by the numeral 83 between the time t14 to t15 in FIG. 5.

Thereafter, the nozzle moving mechanism 21 moves the dispensing nozzle 11 from the standby pot 23 to the above of the substrate W. At time t16, the needle 62 is moved downwardly for flow regulation. At time t17, the on-off valve 17 is turned on to dispense the processing liquid from the dispensing nozzle 11. Moreover, at time t18, the on-off valve 17 is turned off to stop dispensation of the processing liquid from the dispensing nozzle 11. At time t19, the diaphragm 66 cooperating with the needle 62 performs suck back.

In addition, at the time t13, the lowering speed of the needle 62 (see the gradient 81 in FIGS. 3 and 5) may be adjusted such that the flow rate is equal to or close to the flow rate F at the position NC of the needle 62 above the substrate W to push out the processing liquid from the dispensing nozzle 11 for flow regulation. Then, the on-off valve 17 may be turned on subsequent1y.

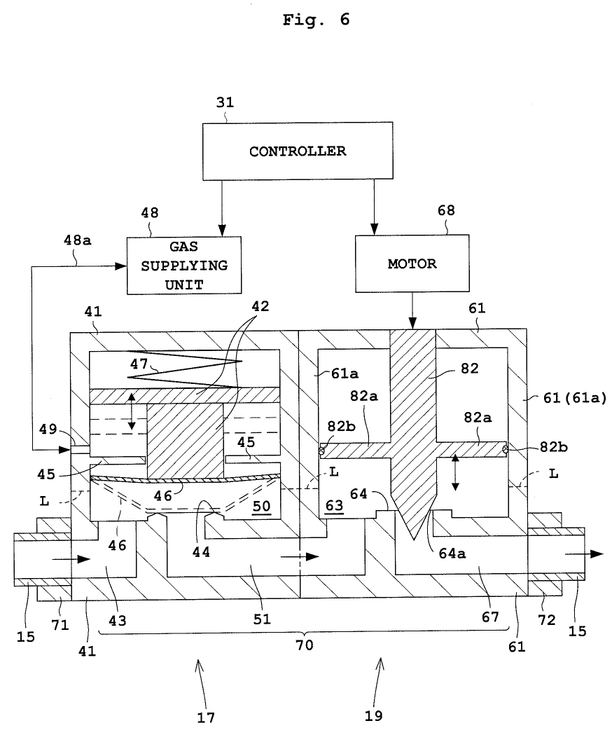

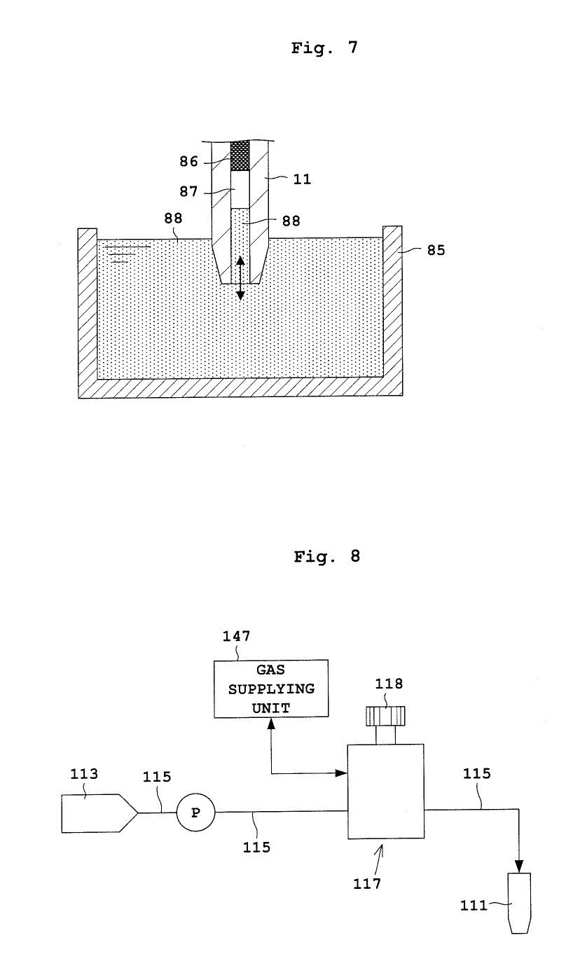

(2) In the embodiments and the modification (1) mentioned above, the diaphragm 66 is provided as the volume variation unit of the suck back valve 19. In contrast to this, as in FIG. 6, the needle 82 may include a partition 82a across the moving direction of the needle 82, and the partition 82a may be movable while contacting to the side inner wall of the valve chamber 61 via a sealed holder 82b such as an O-ring.

(3) In the embodiments and the modifications mentioned above, the developer is occasionally used as the processing liquid. This allows prevention of drips of the developer, leading to flow regulation of the developer. As illustrated in FIG. 7, the controller 31 causes the nozzle moving mechanism 21 to move the dispensing nozzle 11 to the standby pot 23 where the tip end of the dispensing nozzle 11 is immersed into the container 85 in which deionized water remains. Then, the controller 31 causes the motor 68 of the suck back valve 19 to reciprocate the diaphragm 66 cooperating with the needle 62 while the upstream flow path 43 is closed. The tip end of the dispensing nozzle 11 is immersed into the deionized water, and the deionized water is sucked, the sucked deionized water is retained for a given period of time, or the sucked deionized water is pushed out, whereby the tip end of the dispensing nozzle 11 is cleanable. FIG. 7 illustrates a developer layer by the numeral 86, a gas layer such as air by the numeral 87, and the deionized water by the numeral 88.

(4) In the embodiments and the modifications mentioned above, the on-off valve 17 is an air operated valve, but may be a motor driven valve such as the suck back valve 19. In addition, the valve element of the on-off valve 17 is composed of the diaphragm 46, but may allow flow regulation such as the needle 62 of the suck back valve 19. The on-off valve 17 has the configuration as FIG. 2, but may have another known configuration.

(5) In the embodiments and the modifications mentioned above, the processing liquid flows at the suck back reference position SB0. Alternatively, no processing liquid may flow at the suck back reference position SB0 as necessary.

(6) In the embodiments and the modifications mentioned above, each flow path in the suck back valve 19 is formed as a single part, but may be an individual part. That is, the on-off valve 17 and the suck back valve 19 are formed individually. In this case, the on-off valve 17 is connected to the suck back valve 19 via the processing liquid pipe 15.

### REFERENCE SIGNS LIST

1 . . . substrate treating apparatus

3 . . . processing liquid supplying unit

11 . . . dispensing nozzle

15 . . . processing liquid pipe

17 . . . on-off valve

19 . . . suck back valve

31 . . . controller

43 . . . upstream flow path

50 . . . on-off chamber internal flow path

51 . . . coupling flow path

62, 82 . . . needle

63 . . . valve chamber internal flow path

66 . . . diaphragm

67 . . . downstream flow path

68 . . . motor

70 . . . processing liquid flow path

81 . . . gradient

t0 to t8, t1l to t19 . . . time

1. A processing liquid supplying apparatus, comprising:
a processing liquid flow path that passes a processing liquid;
an on-off valve that opens/closes the processing liquid flow path;
a valve element disposed downstream of the on-off valve for adjusting an aperture of the processing liquid flow path;
a volume variation unit disposed downstream of the on-off valve for cooperating with the valve element to vary a volume of a downstream processing liquid flow path disposed downstream of the on-off valve;
a valve element drive unit that drives the valve element; and
a controller that causes the valve element drive unit to move the volume variation unit cooperating with the valve element for increasing the volume of the downstream processing liquid flow path when the on-off valve closes the processing liquid flow path, and causes the valve element drive unit to move the valve element for regulating a flow rate of the processing liquid when the on-off valve opens the processing liquid flow path.

2. The processing liquid supplying apparatus according to claim 1, wherein the valve element drive unit is a motor.

3. The processing liquid supplying apparatus according to claim 1, wherein
the controller causes the valve element drive unit to move the valve element to a suck back reference position for decreasing the flow rate of the processing liquid, and then causes the on-off valve to close the processing liquid flow path and causes the valve element drive unit to move the volume variation unit cooperating with the valve element for increasing the volume of the processing liquid flow path.

4. The processing liquid supplying apparatus according to claim 1, wherein
the controller causes the valve element drive unit to move the valve element from a position of the valve element with the increased volume of the downstream processing liquid flow path to a position where the flow rate is changed to a preset flow rate and causes the on-off valve to open the processing liquid flow path.

5. The processing liquid supplying apparatus according to claim 4, wherein
the valve element is moved upward to the position where the flow rate is changed to the preset flow rate when the on-off valve opens the processing liquid flow path.

6. The processing liquid supplying apparatus according to claim 4, wherein
a lowering speed of the valve element is changed in such a manner that the flow rate is changed to the preset flow rate when the valve element drive unit causes the valve element to move downwardly to the position where the flow rate is changed to the preset flow rate.

7. The processing liquid supplying apparatus according to claim 1, wherein
the processing liquid flow path is formed by a single part.

8. The processing liquid supplying apparatus according to claim 1, further comprising:
a dispensing nozzle disposed downstream of the valve element, the dispensing nozzle being connected to the processing liquid flow path via a pipe for dispensing the processing liquid.

9. The processing liquid supplying apparatus according to claim 1, wherein
the processing liquid is a developer.

10. The processing liquid supplying apparatus according to claim 1, wherein
the controller causes the valve element drive unit to reciprocate the volume variation unit cooperating with the valve element when the on-off valve closes the processing liquid flow path.

11. A method of controlling a processing liquid supplying apparatus, the apparatus including a processing liquid flow path that passes a processing liquid, an on-off valve that opens/closes the processing liquid flow path, a valve element disposed downstream of the on-off valve for adjusting an aperture of the processing liquid flow path, a volume variation unit disposed downstream of the on-off valve for varying a volume of a downstream processing liquid flow path disposed downstream of the on-off valve, and a valve element drive unit that drives the valve element, the method comprising the steps of:
increasing the volume of the downstream processing liquid flow path by causing the valve element drive unit to move the volume variation unit cooperating with the valve element when the on-off valve closes the processing liquid flow path; and
regulating a flow rate of the processing liquid by causing the valve element drive unit to move the valve element when the on-off valve opens the processing liquid flow path.
